(19) United States
(12) Patent Application Publication
(10) Pub. No.: US 2019/0017163 A1
(43) Pub. Date: Jan. 17, 2019

(54) EVAPORATION APPARATUS, EVAPORATION EQUIPMENT, AND EVAPORATION METHOD OF DISPLAY SUBSTRATE

(71) Applicant: Wuhan China Star Optoelectronics Semiconductor Display Technology Co., Ltd., Wuhan, Hubei (CN)

(72) Inventors: Fan TANG, Shenzhen, Guangdong (CN); YungSheng CHEN, Shenzhen, Guangdong (CN)

(73) Assignee: Wuhan China Star Optoelectronics Semiconductor Dis play Technology Co., Ltd., Wuhan, Hubei (CN)

(21) Appl. No.: 15/736,660

(22) PCT Filed: Sep. 20, 2017
(86) PCT No.: PCT/CN2017/102357

§ 371 Date: Dec. 14, 2017

(30) Foreign Application Priority Data
Jul. 13, 2017 (CN) 201710571114.5

(51) Int. Cl. C23C 14/24; C23C 14/04; C23C 14/12; H01L 51/00; H01L 51/56

(52) U.S. Cl. CPC C23C 14/24; C23C 14/042; H01L 51/56; H01L 51/0011; H01L 51/001; C23C 14/12

(57) ABSTRACT

The disclosure discloses an evaporation apparatus, an evaporation equipment, and an evaporation method of a display substrate, the evaporation apparatus of a display substrate includes an evaporation source, a regulation mechanism, and a mask plate; the regulation mechanism may filter the evaporation particles having an incident angle a of the evaporation source smaller than or equal to a predetermined incident angle. The disclosure can effectively reduce the shadow pattern generated during the evaporation process.

### TECHNICAL FIELD

The disclosure relates to the field of organic light emitting diode displays, and more particularly to an evaporation apparatus, an evaporation equipment, and an evaporation method of a display substrate.

### BACKGROUND OF RELATED ART

At present, the manufacturing method of the small and medium-sized organic light-emitting diode (OLED) panel is mainly fine metal mask plate (FMM) method; however, during the FMM evaporation process, due to the effect of the thickness of the mask plate, the acute angle of the via hole, and the height of the surface of the attached substrate, the incident angle of evaporating the material has a great influence on the size of the shadow pattern, the larger the angle of evaporating the material is, the larger the corresponding shadow pattern is, which limits the fabrication of the high-resolution panel. This needs to be improved from two aspects. In one aspect, it is necessary to improve by reducing the thickness of the mask plate, increasing the acute angle of the via hole of the mask plate, and reducing the height of the surface of the attached substrate, but the thickness of the mask plate is difficult to be reduced, and the acute angle of the via hole of the mask plate is also difficult to be increased due to the limit of the etching process of fabricating the mask plate. In the other aspect, it is necessary to improve the evaporation source and increase the incident angle of the material to the attached substrate; the conventional method is to increase the distance between the evaporation source and the attached substrate, but this will increase the size of the chamber, and consequently the utilization factor of the material is lowered and the degree of vacuum is difficult to be lowered.

The existing evaporation source is mainly used to set the angle limiting plate beside the evaporation source nozzle, the smaller the distance between the nozzles is, the better the uniformity of corresponding film thickness is, but the distance between the nozzles affects the setting of the angle limiting plate, which is a relationship of mutual restraint.

The inventor of the present application has found in a long-term research and development that the SUNIC company proposed a planar evaporation source solution to solve the problem of shadow pattern in 2016; the SUNIC technical proposal is to deposit the organic material on the surface of an attached substrate and then place the attached substrate under the mask plate, and then evaporate the material on the surface the attached substrate to the target substrate by using a flash evaporation method. Since this attached substrate is equivalent to the evaporation source, the incident angle of the evaporation particles to the attached substrate is close to vertical incidence of 90 degree, the corresponding shadow pattern can be reduced to less than 1 um, the SUNIC company claims that this method can be used to fabricate devices up to 2500 resolution. However, this method requires the deposition of organic material on the surface of the attached substrate, so a longer TACT time is required. In order to meet the requirements of co-evaporation and doping, the flash evaporation method is used. The temperature of the attached substrate to be heated is much higher than the evaporating temperature of the material, which brings the risk of material decomposition, the heating way of flash evaporation also brings some difficulties. Simultaneously, the utilization factor of materials is also greatly reduced.

### SUMMARY

The disclosure mainly provides an evaporation apparatus, an evaporation method, and an evaporation equipment of a display substrate to solve the problem that in the evaporation operation of the prior art, since the incident angle of the evaporation particles becomes larger, it causes that the shadow pattern formed by the evaporation particles incident to the attached substrate becomes larger, so that the fabrication of the high-resolution panel is limited.

To solve the technical problems, the technical proposal adopted by the disclosure is as follows:

An evaporation apparatus of a display substrate, applied to evaporate target material to surface of an attached substrate, including an evaporation source, a regulation mechanism, and a mask plate; wherein the regulation mechanism may filter evaporation particles having an incident angle of the evaporation source less than or equal to a predetermined incident angle and allow the evaporation particles having an incident angle greater than the predetermined incident angle to pass the mask plate and to deposit on target position of the attached substrate; evaporation particles having an incident angle of the evaporation source less than or equal to a predetermined incident angle and allow the evaporation particles having an incident angle greater than the predetermined incident angle to pass the mask plate and to deposit on the target position of the attached substrate; and the incident angle is an acute angle formed by an incident direction of the evaporation particles and a surface of the mask plate corresponding thereto.

To solve the technical problems, another technical proposal adopted by the disclosure is as follows:

an evaporation equipment of a display substrate, wherein includes an evaporation apparatus, the evaporation apparatus is applied to evaporate target material to surface of an attached substrate, including an evaporation source, a regulation mechanism, and a mask plate;

wherein the regulation mechanism may filter evaporation particles having an incident angle of the evaporation source less than or equal to a predetermined incident angle and passing the evaporation particles having an incident angle greater than the predetermined incident angle, and deposit angle formed on a target position of the attached substrate; and the incident angle is an acute angle formed by an incident direction of the evaporation particles and a surface of the mask plate corresponding thereto.

To solve the technical problems, another technical proposal adopted by the disclosure is as follows:

an evaporation method of a display substrate, including:

providing an evaporation apparatus for depositing a target material on surface of an attached substrate, including an evaporation source, a regulating mechanism, and a mask plate; wherein the regulation mechanism may filter evaporation particles having an incident angle of the evaporation source less than or equal to a predetermined incident angle and allow the evaporation particles having an incident angle greater than the predetermined incident angle to pass the mask plate and to deposit on the target position of the attached substrate, and the incident angle is an acute angle formed by an incident direction of the evaporation particles and a surface of the mask plate corresponding thereto; and using the evaporation apparatus to perform evaporating operation to the attached substrate to form a preset pattern on the attached substrate.

The beneficial effect of the disclosure is that different from the prior art, a regulation mechanism between the evaporation source and the mask plate is added in the disclosure, and the regulation mechanism may filter evaporation particles having an incident angle of the evaporation source less than or equal to a predetermined incident angle, and passing the evaporation particles having an incident angle greater than the predetermined incident angle, and depositing on a target position of the attached substrate, to solve the problem that in the evaporation operation of the prior art, since the incident angle of the evaporation particles becomes larger, it causes that the shadow pattern formed by the evaporation particles incident to the attached substrate becomes larger, so that the fabrication of the high-resolution panel is limited.

### BRIEF DESCRIPTION OF THE DRAWINGS

FIG. 1 is a schematic diagram of a partial structure of the evaporation apparatus of the display substrate according to an embodiment of the disclosure;

FIG. 2 is a schematic diagram of a partial structure that evaporation particles are deposited on the attached substrate after passing through the mask plate to form a target pattern according to an embodiment of the evaporation apparatus of the display substrate of the disclosure;

FIG. 3 is a partial schematic diagram of a structure of a porous plate according to an embodiment of the evaporation apparatus of the display substrate of the disclosure;

FIG. 4 is another partial schematic diagram of the structure of the porous plate according to the embodiment of the evaporation apparatus of the display substrate of the disclosure;

FIG. 5 is still another partial schematic diagram of the structure of the porous plate according to the embodiment of the evaporation apparatus of the display substrate of the disclosure;

FIG. 6 is a partial schematic diagram of a structure of an embodiment according to the evaporation equipment of the di splay substrate of the disclosure;

FIG. 7 is a step flow chart of an embodiment of the evaporation method of the display substrate according to the disclosure.

### DETAILED DESCRIPTION OF EMBODIMENTS

### First Embodiment

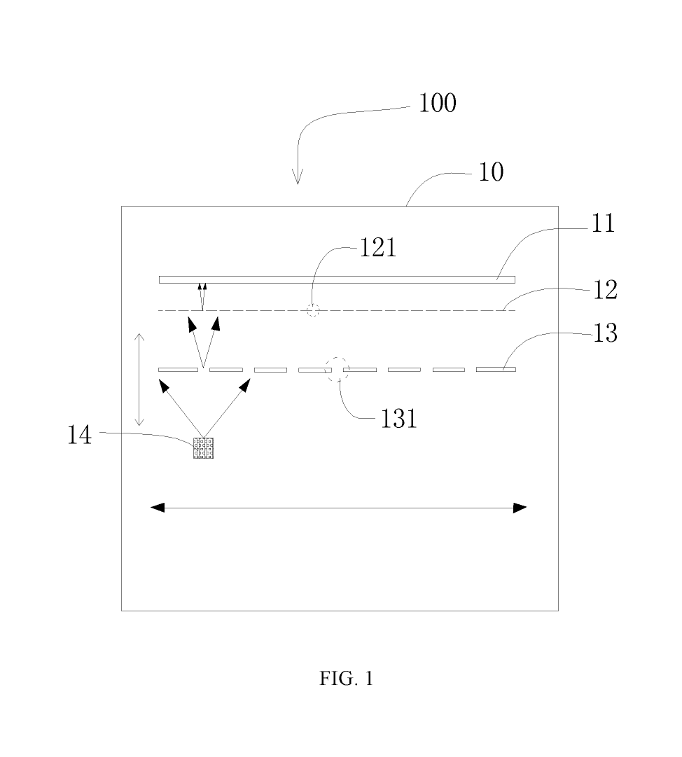

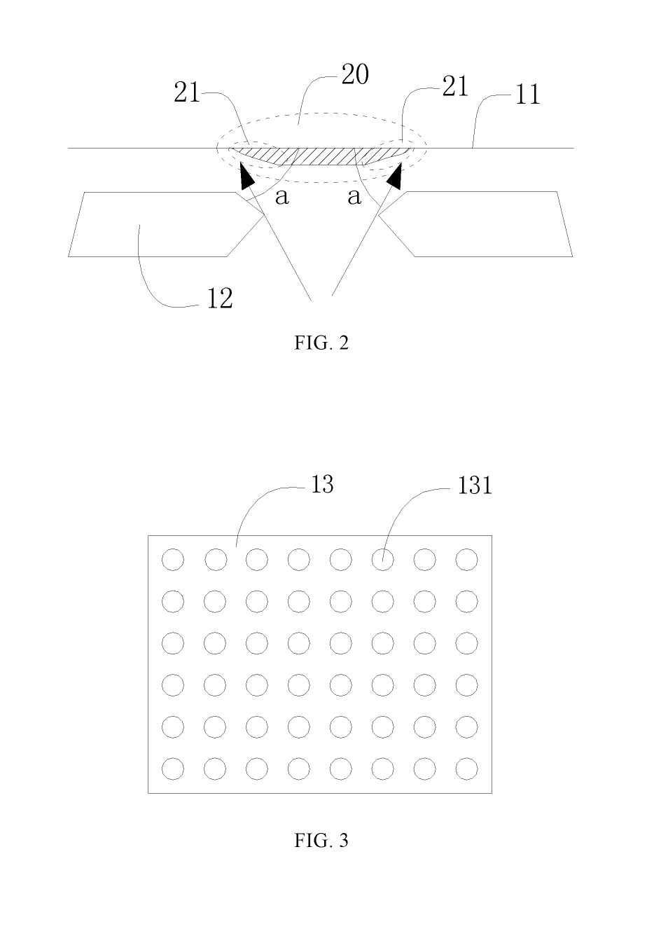

Referring to FIG. 1 and FIG. 2, by analyzing in conjunction with FIGS. 1 and 2, we can get that the evaporation apparatus 100 of the display substrate of the disclosure, applied to evaporate target material to the surface of the attached substrate 11, includes an evaporation source 14, a regulation mechanism, and the mask plate 12.

The regulation mechanism may filter the evaporation particles having an incident angle a of the evaporation source 14 smaller than or equal to a predetermined incident angle, and allow the evaporation particles having an incident angle greater than the predetermined incident angle to pass through the mask plate 12, and to deposit on a target position of the attached substrate 11, and the incident angle a is an acute angle formed by an incident direction of the evaporation particles and a surface of the mask plate 12 or the attached substrate 11 corresponding thereto.

In this embodiment, the regulation mechanism may optionally be a porous plate 13, the porous plate 13 is provided with a plurality of first via holes 131, the spacing between the porous plate 13 and the evaporation source 14 is a first predetermined spacing, the spacing between the porous plate 13 and the mask plate 12 is a second predetermined spacing, the spacing between the mask plate 12 and the attached substrate 11 is a third predetermined spacing, and the first predetermined spacing, the second predetermined spacing, and the third predetermined spacing may only allow the evaporation particles having an incident angle a to be larger than the predetermined incident angle to pass through the first via holes 131 and to be deposit on the target position of the attached substrate 11. After the evaporation particles pass through the porous plate 13 and the mask plate 12, the preset pattern 20 is formed on the attached substrate 11, and the thickness of the middle portion of the preset pattern 20 is generally uniform, but the thickness on both sides is not uniform, but in the form of a slope, such a sloped shape portion of the preset pattern 20 is referred to as a shadow pattern 21. The portion of the middle portion of the preset pattern 20 has substantially no influence on the display effect, but the shadow pattern 21 has a large negative influence on the display effect, resulting in uneven brightness on the entire pixel, so that we need to reduce the coverage area of the shadow pattern 21 as much as possible.

In the present embodiment, the evaporation apparatus 100 of the display substrate of the disclosure further includes an evaporation chamber 10, and the evaporation chamber 10 is a vacuum closed space; the evaporation source 14, the porous plate 13, and the mask plate 12 are provided within the evaporation chamber 10, and are sequentially arranged at equal intervals in parallel in the evaporating direction.

In the present embodiment, the distance between the porous plate 13 and the mask plate 12 may be adjusted, or the distance between the two of the evaporation source 14, the porous plate 13, and the mask plate 12 may be adjusted.

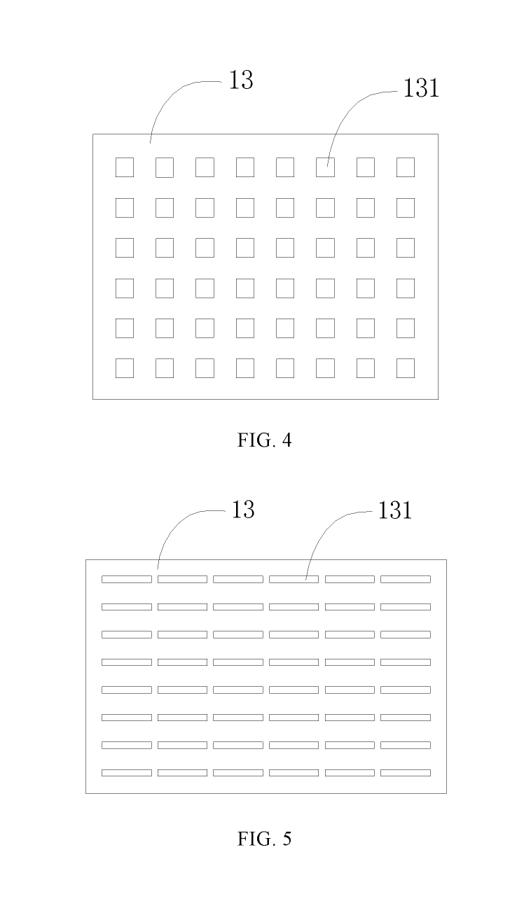

Referring to FIGS. 3, 4 and 5, the cross-sectional shape of the first via holes 131 may be selected as one of circular, square, trapezoidal or prismatic, or other shapes. The cross-sectional shape of the first via holes 131 of FIG. 3 is circular, the cross-sectional shape of the first via holes 131 of FIG. 4 is square, the cross-sectional shape of the first via hole 131 as shown in FIG. 5 is rectangular, and the cross-sectional shape of the first via hole 131 being elliptical or prismatic is omitted. The size of the plurality of the first via holes 131 on the porous plate 13 may be selected to be uniform or non-uniform, and the arrangement thereof may be in a uniform arrangement or in a non-uniform arrangement. The aperture of the porous plate 13 is in the range of 1 mm to 100 mm, may be selected as 10 mm, 20 mm, 50 mm or 80 mm, and the thickness of the porous plate 13 is in the range of 0.1 mm to 10 mm, may be selected as 0.2 mm, 0.5 mm, 0.7 mm or 0.8 mm.

In the present embodiment, the mask plate 12 is provided with a plurality of second via holes 121, the aperture of the first via hole 131 is larger than that of the second via hole 121, such that one first via hole 131 may correspond to a plurality of the second via holes 121, and translating the attached substrate 11 with respect to the porous plate 13 is not necessary during the evaporation process. So that one first via hole 131 can correspond to a plurality of the second via holes 121, and translating the attached substrate 11 with respect to the porous plate 13 is not necessary during the evaporation process. The projection of the mask plate 12 on the attached substrate 11 is within the projection of the porous plate 13 on the attached substrate 11 or the projection of the porous plate 13 on the attached substrate 11 is within the mask plate 12 is within the projection on the attached substrate 11. The area of the mask plate 12 is larger than the area of the attached substrate 11, and the mask plate 12 covers the attached substrate 11 in the evaporating direction; the area of the porous plate 13 is larger than the area of the attached substrate 11, and the porous plate 13 covers the mask plate 12 in the evaporating direction.

In the present embodiment, the first predetermined spacing between the attached substrate 11 and the mask plate 12 is small, and is not so large as shown in FIG. 1 (FIG. 1 makes the spacing between the two be larger only for better visual representation), the attached substrate 11 and the mask plate 12 are substantially stacked together.

Described in conjunction with FIG. 2, the smaller angle formed by the incident direction of evaporation particles and the attached substrate 11 is defined as the acute angle a, as shown in FIG. 2, when the evaporation particles passes through the mask plate 12 to reach the attached substrate 11, the evaporation particles are affected by the acute angle and the height of the second via holes 121 of the mask plate 12 and produce the shadow pattern 21; the smaller the incident angle a of the evaporation particles are, correspondingly, the lager the shadow pattern 21 produced by the evaporation particles deposited on the attached substrate 11 is. When using the conventional evaporation method, the incident angle a of the evaporation particles is generally at 50 to 70 degree, theoretically, when the angle between the evaporation particles 11 and the attached substrate is 90 degree, the mask plate 12 has no influence on the deposition of the evaporation particles pattern 21, and the shadow pattern 21 will not be produced, which is an ideal case, in reality there is no such an evaporation source 14; when using a planar evaporation source 14, the angle between the evaporation particles and the attached substrate can be achieved up to 80 degree or more, but using the planar evaporation source 14 has a series of problems, such as the requirement of co-evaporation and doping.

As shown in FIGS. 1 and 2, the technical proposal of the disclosure provides a porous plate 13 between the mask plate 12 and the evaporation source 14, when the evaporation particles from the evaporation source 14 are passing the porous plate 13, the evaporation particles having small incident angle a are filtered by the porous plate 13, and the evaporation particles having large incident angle a are deposited on the target position of the attached substrate 11 after passing through the porous plate 13 and the mask plate 12. The first via holes 131 of the porous plate 13 are heated during using process, and the heating temperature is greater than the evaporation temperature of the vapor evaporation particles to avoid the evaporation particles depositing in the first via holes 131 of the porous plate 13 during the evaporation process, causing the first via holes 131 to clog or the occurrence of an effective opening area reduction of the first via holes 131. Simultaneously, part of the evaporation particles having a small incident angle a are rebounded after bumping the first via holes 131 of the heated porous plate, and the rebounded parts may also be deposited on the attached substrate 11 through the porous plate 13. The distances of the porous plate 13 from the evaporation source 14 and from the mask plate 12 can be adjusted to meet the requirements of film thickness uniformity, smaller shadow pattern 21 and larger material utilization factor. The evaporation source 14 may be a linear evaporation source 14, the evaporation source 14 scans the porous plate 13 to complete the evaporation, and the evaporation source 14 may also be an organic jet evaporation source 14, and the material jet head may scan the porous plate 13 to complete the evaporating operation.

By analyzing in conjunction with FIG. 2, we can conclude that when the incident angle a is large, the coverage area of the corresponding shadow pattern 21 is small, on the contrary the coverage area of the shadow pattern 21 is large. For the evaporation apparatus having the porous plate 13, the incident angle can be set larger than the preset incident angle, so that the coverage area of the shadow pattern 21 on the attached substrate 11 can be greatly reduced, and the evaporation apparatus 100 of the display substrate having the porous plate 13 can handle the fabrication of high-resolution panels. Meanwhile, since the corresponding shadow pattern 21 in the pixel is smaller, light emission luminance of the pixel is not only more uniform, but also the probability of shorting between cathode and anode (A-C short) is reduced. Furthermore, due to the arrangement of the porous plate 13, the incident angle of the evaporation particles passing through the porous plate 13 is reduced, the distance between the evaporation source 14 and the attached substrate can be further and material utilization factor is improved.

In the disclosure, by adding a regulating mechanism, that is, the porous plate 13, between the evaporation source 14 and the mask plate 12, the evaporation particles jetted by the evaporation source 13 at the incident angle a less than or equal to the predetermined incident angle are filtered, and the evaporation particles having the incident angle a larger than the predetermined incident angle are allowed to pass through the mask plate 12, and to deposit on the target position of the attached substrate 11; simultaneously, while heating the first via holes 131 of the porous plate 13 in the evaporation process, temperature of the first via holes 131 is set larger than the evaporation temperature to avoid the evaporation particles depositing in the first via holes 131 of the porous plate 13 during the evaporation process, causing the first via holes 131 to clog or the occurrence of an effective opening area reduction of the first via holes 131, thereby the problem is solved that during the evaporation operation of the prior art, since the incident angle of the evaporation particles becomes larger, the shadow pattern formed by the evaporation particles incident to the attached substrate becomes larger, so that the fabrication of the high-resolution panel is limited.

### Second Embodiment

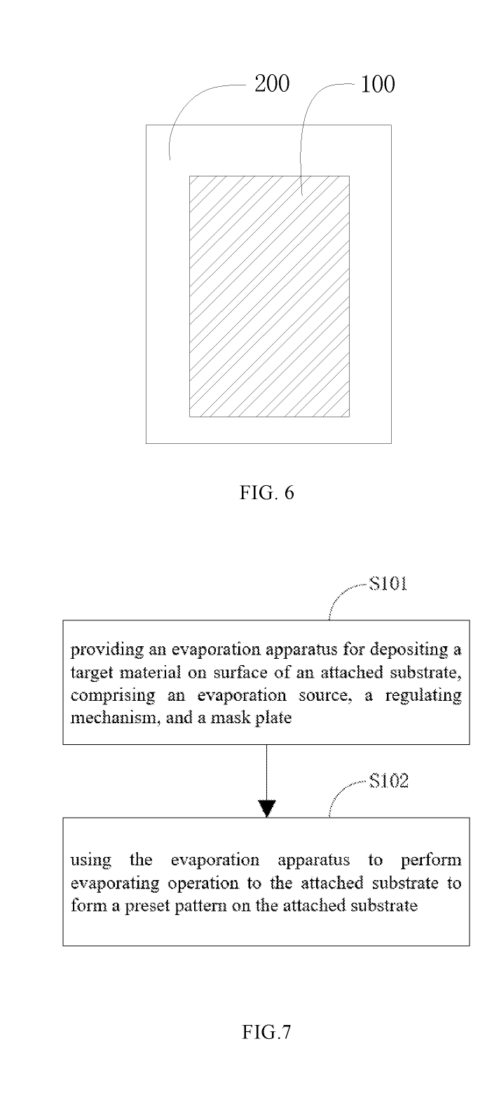

Referring to FIG. 6, as seen in conjunction with FIG. 6, the evaporation equipment 200 of the display substrate of the disclosure includes the evaporation apparatus 100 of the display substrate according to the first embodiment, since the evaporation apparatus 100 has been described in detail in the first embodiment, the description thereof will not be repeated here.

In the disclosure, by adding a regulating mechanism, that is, the porous plate 13, between the evaporation source 14 and the mask plate 12, the evaporation particles jetted by the evaporation source 13 at the incident angle a less than or equal to the predetermined incident angle are filtered, and the evaporation particles having the incident angle a larger than the predetermined incident angle are allowed to pass through the mask plate 12, and to deposit on the target position of the attached substrate 11; simultaneously, while heating the first via holes 131 of the porous plate 13 in the evaporation process, temperature of the first via holes 131 is set larger than the evaporation temperature to avoid the evaporation particles depositing in the first via holes 131 of the porous plate 13 during the evaporation process, causing the first via holes 131 to clog or the occurrence of an effective opening area reduction of the first via holes 131, thereby the problem is solved that during the evaporation operation of the prior art, since the incident angle of the evaporation particles becomes larger, the shadow pattern formed by the evaporation particles incident to the attached substrate becomes larger, so that the fabrication of the high-resolution panel is limited.

### Third Embodiment

Referring to FIGS. 7, 1, and 2, as seen in conjunction with FIGS. 7, 1, and 2 that the evaporation method of the display substrate of the disclosure includes the steps of:

step S101: providing an evaporation apparatus 100 for depositing a target material on surface of an attached substrate 11, including an evaporation source 14, a regulating mechanism, and a mask plate 12;

the regulation mechanism may filter the evaporation particles having an incident angle a of the evaporation source 14 smaller than or equal to a predetermined incident angle, and allow the evaporation particles having an incident angle greater than the predetermined incident angle to pass through the mask plate 12 and to deposit on a target position of the attached substrate 11, and the incident angle a is an acute angle formed by an incident direction of the evaporation particles and a surface of the mask plate 12 corresponding thereto.

Step S102: using the evaporation apparatus to perform evaporating operation to the attached substrate 11 to form a preset pattern 20 on the attached substrate 11.

In the present embodiment, the regulating mechanism is a porous plate 13, a plurality of first via holes 131 on the porous plate 13, the first via holes 131 are in a heated state during the evaporation process, and the temperature of the first via holes 131 are maintained above the evaporation temperature. In addition, the porous plate 13 is not heated except for the first via holes 131, and the purpose is to avoid thermal expansion.

In the present embodiment, the distance between the porous plate 13 and the mask 12 may be adjusted, or the distance between the two of the evaporation source 14, the porous plate 13, and the mask plate 12 may be adjusted.

In the disclosure, by adding a regulating mechanism, that is, the porous plate 13, between the evaporation source 14 and the mask plate 12, the evaporation particles jetted by the evaporation source 13 at the incident angle a less than or equal to the predetermined incident angle are filtered, and the evaporation particles having the incident angle a larger than the predetermined incident angle are allowed to pass through the mask plate 12, and to deposit on the target position of the attached substrate 11; simultaneously, while heating the first via holes 131 of the porous plate 13 in the evaporation process, temperature of the first via holes 131 is set larger than the evaporation temperature to avoid the evaporation particles depositing in the first via holes 131 of the porous plate 13 during the evaporation process, causing the first via holes 131 to clog or the occurrence of an effective opening area reduction of the first via holes 131, thereby the problem is solved that during the evaporation operation of the prior art, since the incident angle of the evaporation particles becomes larger, the shadow pattern formed by the evaporation particles incident to the attached substrate becomes larger, so that the fabrication of the high-resolution panel is limited.

Above are only embodiments of the disclosure is not patented and therefore limit the scope of the disclosure, the use of any content of the present specification and drawings made equivalent or equivalent structural transformation process, either directly or indirectly related to the use of other technologies areas are included in the same way the scope of the patent protection of the disclosure.

What is claimed is:

1. An evaporation apparatus of a display substrate, applied to evaporate target material to surface of an attached substrate, comprising an evaporation source, a regulation mechanism, and a mask plate;
wherein the regulation mechanism may filter evaporation particles having an incident angle of the evaporation source less than or equal to a predetermined incident angle and allow the evaporation particles having an incident angle greater than the predetermined incident angle to pass the mask plate and to deposit on target position of the attached substrate; and the incident angle is an acute angle formed by an incident direction of the evaporation particles and a surface of the mask plate corresponding thereto.

2. The evaporation apparatus of the display substrate according to claim 1, wherein the regulation mechanism is a porous plate, and the porous plate is provided with a plurality of first via holes; spacing between the porous plate and the evaporation source is a first predetermined spacing, spacing between the porous plate and the mask plate is a second predetermined spacing, and spacing between the mask plate and the attached substrate is a third predetermined spacing; the first predetermined spacing, the second predetermined spacing, and the third predetermined spacing may only allow the evaporation particles having an incident angle greater than the predetermined incident angle to pass through the first via holes and to deposit on the target position of the attached substrate.

3. The evaporation apparatus of the display substrate according to claim 2, wherein the evaporation apparatus further comprises an evaporation chamber, the evaporation chamber is a vacuum closed space, the evaporation source, the porous plate, and the mask plate are provided in the evaporation chamber, and sequentially arranged at equal intervals in parallel in a evaporating direction.

4. The evaporation apparatus of the display substrate according to claim 2, wherein distance between the porous plate and the mask plate may be adjusted, or distance between the two of the evaporation source, the porous plate, and the mask plate may be adjusted.

5. The evaporation apparatus of the display substrate according to claim 2, wherein the mask plate is provided with a plurality of second via holes, aperture of the first via hole is larger than that of the second via hole, and cross-sectional shape of the first via hole is one of a circular, square, trapezoidal or prismatic shape.

6. The evaporation apparatus of the display substrate according to claim 2, wherein projection of the mask plate projected on the attached substrate is located within projection of the porous plate projected on the attached substrate, or the projection of the porous plate projected on the attached substrate is within the projection of the mask plate on the attached substrate.

7. An evaporation equipment of a display substrate, wherein comprises an evaporation apparatus, the evaporation apparatus is applied to evaporate target material to surface of an attached substrate, and the evaporation apparatus comprises an evaporation source, a regulation mechanism, and a mask plate;
wherein the regulation mechanism may filter evaporation particles having an incident angle of the evaporation source less than or equal to a predetermined incident angle and allow the evaporation particles having an incident angle greater than the predetermined incident angle to pass through the mask plate and to deposit on a target position of the attached substrate; and the incident angle is an acute angle formed by an incident direction of the evaporation particles and a surface of the mask plate corresponding thereto.

8. The evaporation equipment of the display substrate according to claim 7, wherein the regulation mechanism is a porous plate, and the porous plate is provided with a plurality of first via holes; spacing between the porous plate and the evaporation source is a first predetermined spacing, spacing between the porous plate and the mask plate is a second predetermined spacing, and spacing between the mask plate and the attached substrate is a third predetermined spacing; the first predetermined spacing, the second predetermined spacing, and the third predetermined spacing may only allow the evaporation particles having an incident angle greater than the predetermined incident angle to pass through the first via holes and to deposit on the target position of the attached substrate.

9. The evaporation equipment of the display substrate according to claim 8, wherein the evaporation apparatus further comprises an evaporation chamber, the evaporation chamber is a vacuum closed space, the evaporation source, the porous plate, and the mask plate are provided in the evaporation chamber, and sequentially arranged at equal intervals in parallel in a evaporating direction.

10. The evaporation equipment of the display substrate according to claim 8, wherein distance between the porous plate and the mask plate may be adjusted.

11. The evaporation equipment of the display substrate according to claim 8, wherein distance between the two of the evaporation source, the porous plate, and the mask plate may be adjusted.

12. The evaporation apparatus of the display substrate according to claim 8, wherein the mask plate is provided with a plurality of second via holes, aperture of the first via hole is larger than that of second via hole, and cross-sectional shape of the first via hole is one of a circular, square, trapezoidal or prismatic shape.

13. The evaporation apparatus of the display substrate according to claim 8, wherein projection of the mask plate projected on the attached substrate is located within projection of the porous plate projected on the attached substrate, or the projection of the porous plate projected on the attached substrate is within the projection of the mask plate on the attached substrate.

14. An evaporation method of a display substrate, comprising:
providing an evaporation apparatus for depositing a target material on surface of an attached substrate, comprising an evaporation source, a regulating mechanism, and a mask plate;
wherein the regulation mechanism may filter evaporation particles having an incident angle of the evaporation source less than or equal to a predetermined incident angle and allow the evaporation particles having an incident angle greater than the predetermined incident angle to pass through the mask plate and to deposit on a target position of the attached substrate;
and using the evaporation apparatus to perform evaporating operation to the attached substrate to form a preset pattern on the attached substrate.

15. The evaporation method of the display substrate according to claim 14, wherein the regulation mechanism is a porous plate, and the porous plate is provided with a plurality of first via holes, the first via holes are in a heated state during evaporation process, and temperature of the first via holes are maintained above the evaporation temperature.

16. The evaporation method of the display substrate according to claim 14, wherein distance between the porous plate and the mask plate may be adjusted, or distance between the two of the evaporation source, the porous plate, and the mask plate may be adjusted.
